(19) United States
(12) Patent Application Publication
(10) Pub. No.: US 2008/0186864 A1
(43) Pub. Date: Aug. 7, 2008

(54) Flexible Cost and Constraint Assignment Method and System For Hierarchical Networks

(75) Inventor: Tsz-Tak Daniel Ho, Palo Alto, CA (US)

Correspondence Address: Michele Baillie, P.O BOX 683, MARBLEHEAD, MA, 01945, US

(73) Assignee: MOTIPATE, INC., Palo Alto, CA (US)

(21) Appl. No.: 12/022,882

(22) Filed: Jan. 30, 2008

Related U.S. Application Data
(60) Provisional application No. 60/899,265, filed on Feb. 2, 2007.

(51) Int. Cl. G01R 31/08

(52) U.S. Cl. 370/238

(57) ABSTRACT

A method and system for flexible cost management in a hierarchical network is disclosed. The method and system define paths and a cost function for each type of node in a hierarchical network. The cost function depends on the hierarchical level of the node, cost function of the node's parent node, and cost functions for the node's child nodes. Constraints can be placed on the costs of the nodes by introducing time periods and/or various user defined criteria in their cost functions. Constraints on the total network can also be defined to bound the total cost of the network. In this manner, flexibility is injected in the management of costs in the hierarchical network.

### CROSS-REFERENCE TO RELATED APPLICATIONS

This application claims priority to co-pending U.S. Provisional Patent application, entitled “Flexible Cost and Constraint Assignment Method and System for Hierarchical Network”, Ser. No. 60/899,265, filed on Feb. 2, 2007.

### BACKGROUND

1. Field

The invention relates to hierarchical networks, and more particularly to the assignment of cost functions and constraints to nodes and the entire network in hierarchical networks.

2. Related Art

In order to build an online network, such as a social network, the desirable user behavior is to encourage contacts between users in a hierarchical manner. For example, in a social network, a user is encouraged to invite his/her friends to join the network, and those that join further invite their friends to join the network. FIG. 1 illustrates such an example hierarchical network, where each node would represent a user in the above example, and each node is assigned a cost function to model the payment to a user for joining the network. In many hierarchical systems, the cost function of a node is usually a fixed cost, i.e., it is assigned a fixed value, without considering that the cost function might be different due to the type of the node it's modeled after, its associated hierarchical level, the cost functions of its parent node or child node(s), etc. Under this model, it will be too rigid to model real life applications of a hierarchical network. In addition, the cost of the network can become uncontrollable if no constraints are set to control the cost of each node when the network grows.

Accordingly, there exists a need for an improved method and system to manage the constraint and cost functions of a hierarchical network. The invention addresses such a need.

### SUMMARY

The invention provides a method and system for managing constraint and cost functions of a hierarchical network. Since a network can grow without limit, the system places constraints on the network and assigns cost functions to the cost of the network, so that the total cost of the network can be estimated and controlled. Furthermore, the cost functions of each node will have a fixed cost component, and will also depend on cost function of its parent node, cost functions of its child nodes, hierarchical level of the node, and various users defined criteria such as the type of nodes it's modeled after, etc. In addition, time periods are introduced into the system so that the cost of the network can differ during different time periods. A user can configure the cost functions of a hierarchical network and all the nodes in the network for various scenarios.

### BRIEF DESCRIPTION OF DRAWINGS

FIG. 1 illustrates an example hierarchical network.

FIG. 2 illustrates the identification of specific paths and assignment of costs in a hierarchical network.

FIG. 3 is a flowchart illustrating an exemplary method for flexible cost and constraint assignment.

FIGS. 4a and 4b illustrate examples of flexible cost control in hierarchical networks.

FIG. 5 illustrates an exemplary flexible cost control system.

FIGS. 6A-6C illustrate a third example of flexible cost control in a hierarchical network.

### DETAILED DESCRIPTION

A method and system according to the invention defines a cost function for each type of node in a hierarchical network. Constraints can be placed on the costs of the nodes by introducing time periods and/or user defined criteria in their cost functions. Constraints on the total network can also be defined to bound the total cost of the network. In an exemplary embodiment, the cost of a node in the network depends on the costs of its linked nodes, hierarchical level, time, and user-defined criteria.

The cost function of a particular node can be represented as below:

C_{P(L)}=α+f(C_{P(L-1)},C_{P(L+1)}⁰, . . . , C_{P(L+1)}^{n,L,t,g)}

where α is a constant,

L denotes the hierarchical level of node (p),

C_{P(L)} denotes the cost function of a node (p) at level L,

C_{P(L-1)} denotes the cost function of the parent node of (p) at level L−1,

C_{P(L+1)}⁰, . . . , C_{P(L+1)}ⁿ denotes the cost functions of all its children nodes at level L+1,

t denotes a set of time periods for node (p), and

g denotes user-defined criteria for node (p) (e.g. the type of nodes the node is modeled after, whether the node is in a specific path, etc.).

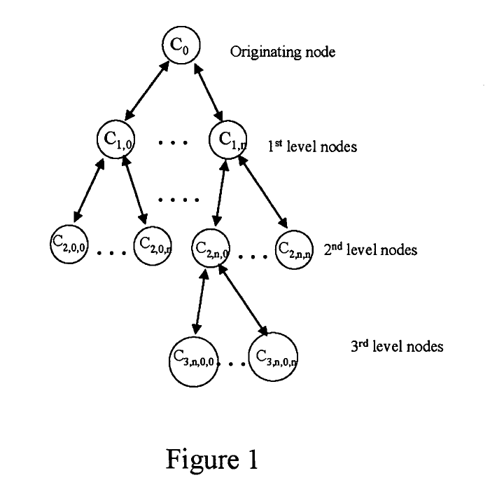

The constant α represents a fixed cost for the node. The variables L, t and g introduce constraints on the cost of the nodes. For example, with the hierarchical network illustrated in FIG. 1, the cost function of node C_{2,n,0} is a function of the cost function of its parent node C_{1,n}, the cost functions of the child nodes C_{3,n,0,0} to C_{3,n,0,n}, and the time periods t and user defined criteria g, as set forth below:

C_{2,n,0}=α+f(C_{1,n},C_{3,n,0,0}, . . . , C_{3,n,0,n,L,t,g)}

Cost of the entire network is:

CN=β+ΣCₜ

where β is a constant,

CN is the cost function of the entire network,

Cᵢ is the cost function of node i in the hierarchical network, and

Σ Cᵢ is the sum of cost functions of all the nodes in the hierarchical network.

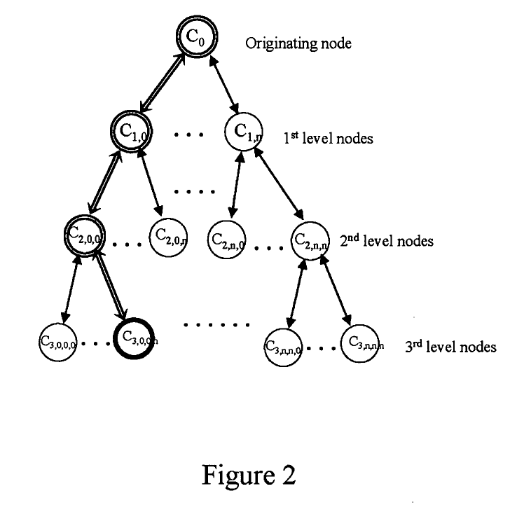

Users can allow an unlimited set of cost assignment and constraints to be applied to the network using programming languages or configuration files. The system and method also have the ability to identify specific paths in the network and assign costs to only nodes in those paths, while costs of all other nodes are assigned different costs as illustrated in FIG. 2. In FIG. 2, the cost functions for all nodes are zero except for those in the path highlighted by concentric and bold circles.

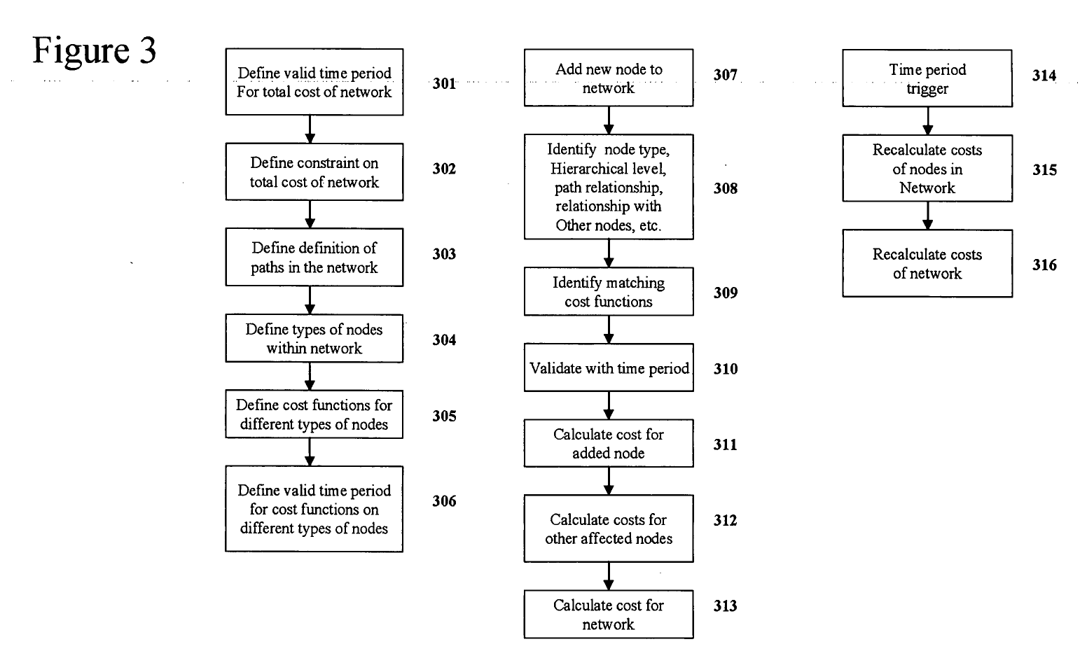

FIG. 3 is a flowchart illustrating an exemplary method for flexible cost and constraint assignment. First, a valid time period is defined for the total cost of the hierarchical network (step 301). The constraints on the total cost of the network are also defined (step 302). The definition of paths and criteria for forming a path in the network are defined (step 303) (e.g. specify what a start node and end node of a path is). The types of nodes within the network are defined (step 304), along with the cost functions of the different types of nodes (step 305). A valid time period, as well as any other user defined criteria, can further be defined for the cost functions on different types of nodes (step 306).

When a new node is added to the network (step 307), the added node's parameters are defined (step 308), including the node type, hierarchical level, path relationship with other nodes in the network, etc. Then, the cost functions matching the added node's parameters are identified (step 309). If the cost functions include valid time periods, then the time period for the added node is validated (step 310). The cost for the added node is then calculated according to the cost functions (step 311). The costs for other affected nodes and the network are calculated as well (steps 312-313).

When a specified time period for the cost functions for the network or any of its nodes is triggered, i.e., expires, (step 314), the costs of the nodes in the network and the cost of the network are recalculated (steps 315-316). The recalculations are performed with cost functions valid for the current time period.

Some sample constraints and cost functions assignable using the method and system for a hierarchical network are show below:
Total cost of the network may be fixed. Each node will have a constant cost function, and once total cost of the nodes exceed the fixed cost, all additional nodes will have a cost function of zero.
Cost of a node is a function of its hierarchical level. (e.g. All level 1 nodes are assigned the same cost, while all level 2 nodes are assigned another cost)
Cost of a node is a function of its child nodes, of which the cost function is a constant plus a certain percentage of the cost functions of all its 1^{st} level child nodes, plus a certain percentage of the cost functions of all its 2^{nd} level child nodes.
Costs of all nodes except nodes in some specific paths are zero.
Cost of a node carries a cost but becomes zero after a set time limit.
Cost of a node carries a higher cost if node represents a user residing in California.

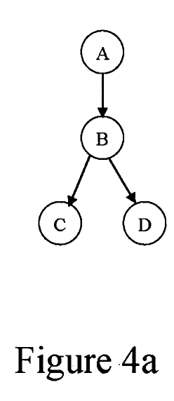

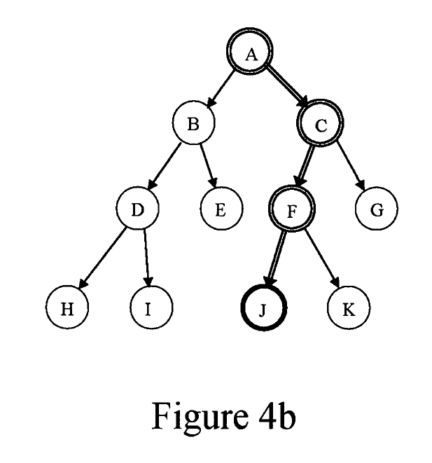

FIG. 4a illustrates a first example of flexible cost control in a hierarchical network. This network is a social network that an original poster uses for recruiting members into the network by paying them. Each member who joins this network will be compensated according to a predefined compensation method, and the compensation will depend on which member recruited the member, the school the member attended, and the members recruited by this member. Assume that Member A (attended University of Iowa) recruits Member B (attended Harvard), and Member B recruits Member C (attended University of Illinois) and Member D (attended University of Sydney in Australia).

The compensation method for this example defines the rules of payment as follows:
a member who attended a US college or university: $2.00;
a member who attended a non-US college or university: $1.00;
a member who was recruited by a member who attended a US college or university: $0.30;
a member who was recruited by a member who attended a non-US college or university: $0.10;
a member who recruits a member who attended a US college or university: $0.50+10% of each child node;
a member who recruits a member who attended a non-US college or university: $0.20+10% of each child node.

Using this compensation method, the members/nodes in the network of FIG. 4a are compensated as follows:
Member C is paid: $2.00+$0.30=$2.30;
Member D is paid: $1.00+$0.30=$1.30;
Member B is paid: $2.00+$0.30+$0.50+$0.20+$2.30×10%+$1.30×10%=$3.36;
Member A is paid: $2.00+$0.50+$3.36×10%=$2.836.

FIG. 4b illustrates a second example of flexible cost control in a hierarchical network. The network is a listing system. An original poster (A) posts an item for sale (e.g. a business), and then sends a notice of the post to various contacts (B and C) to see if they would be interested in the item. If the contacts (B and C) are not interested, they can in turn send out the notice to their own contacts (D-G), and so forth, until a buyer (J) is found and the transaction closes. In this case, the buyer (J), along with the people who refer the buyer (C and F) to the original poster (A), will be compensated. The other contacts in the network who received the notice but did not assist in finding the ultimate buyer will not be compensated.

The compensation method for this example defines payment as follows:
Each node in the path which connects the original poster to the ultimate buyer will be compensated except for the original poster. An amount of $300 will be equally divided by the number of nodes in the connected path.
All other nodes not in the path that connects the original poster to the ultimate buyer will not be paid.

Using this compensation method, the members/nodes in the network of FIG. 4b are compensated as follows:
Node A will be paid nothing;
Node B, D, E, H, I, G, and K will be paid nothing;
Node C, F, and J will each be paid $100.

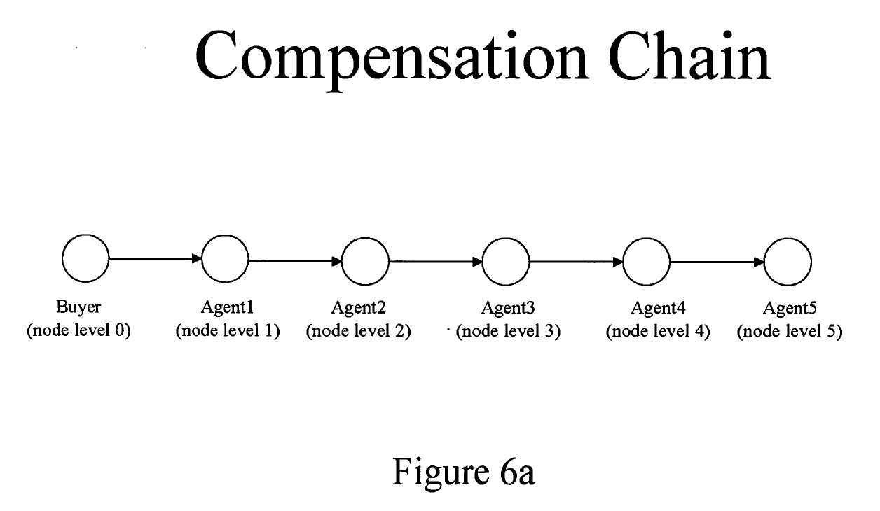

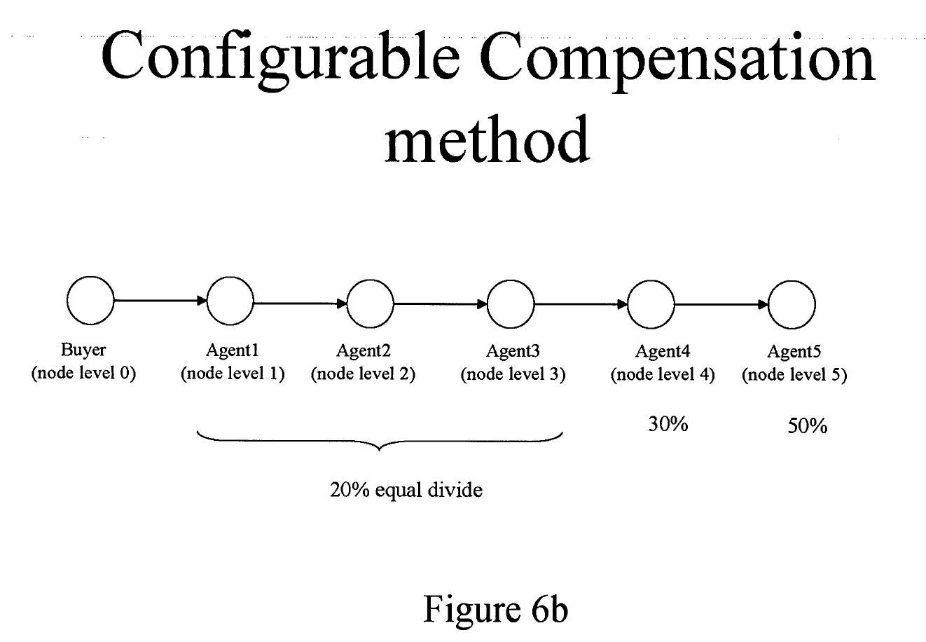

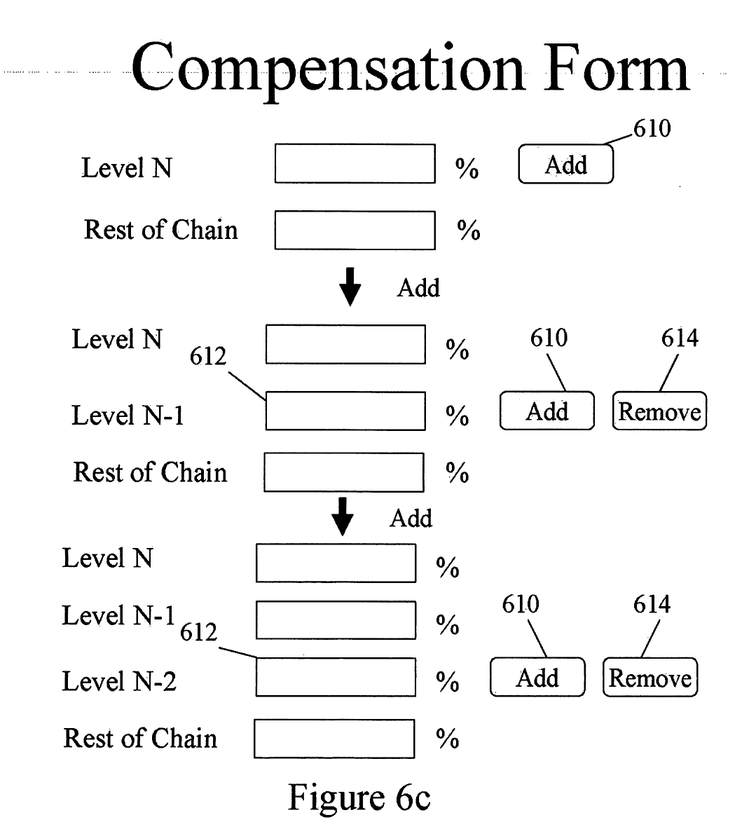

FIGS. 6A-6C illustrate a third example of flexible cost control in a hierarchical network. In this third example, users can utilize the system to define the compensation method by inputting the desired parameters. In a non-local real estate transaction, a buyer usually has a local agent who connects with another agent in another state to search out-of-state properties for the buyer. As illustrated in FIG. 6A, out of the total commission, each agent (Agent1-Agent5) will take his/her portion if they helped in facilitating the transaction. However, an “equal share” method as shown, i.e., dividing the total commissions equally among all agents, may not motivate agents further down the chain from the Buyer, since the last agent who found the property will only get a very small commission if the chain is very lengthy. For example, for a chain of 25 nodes, the last agent will only get 4% of the commission in an ‘equal share’ method. Instead, as illustrated in FIG. 6B, the Buyer may assign a certain percentage to each level of the chain, so that the last agent (Agent5) who really helped to find the property will get a larger portion of the commission.

Configuration of such compensation method can be done through a user interface, an example of which is illustrated in FIG. 6C. A user clicks the Add button 610 for Level N to add the next field 612 for Level N−1. The Add button 610 is now present with the newly added level (Level N−1), along with a new Remove button 614. Clicking the Add button again will add another level (Level N−2), while clicking the Remove button will remove the newly added level (Level N−1), and return the interface to the previous state.

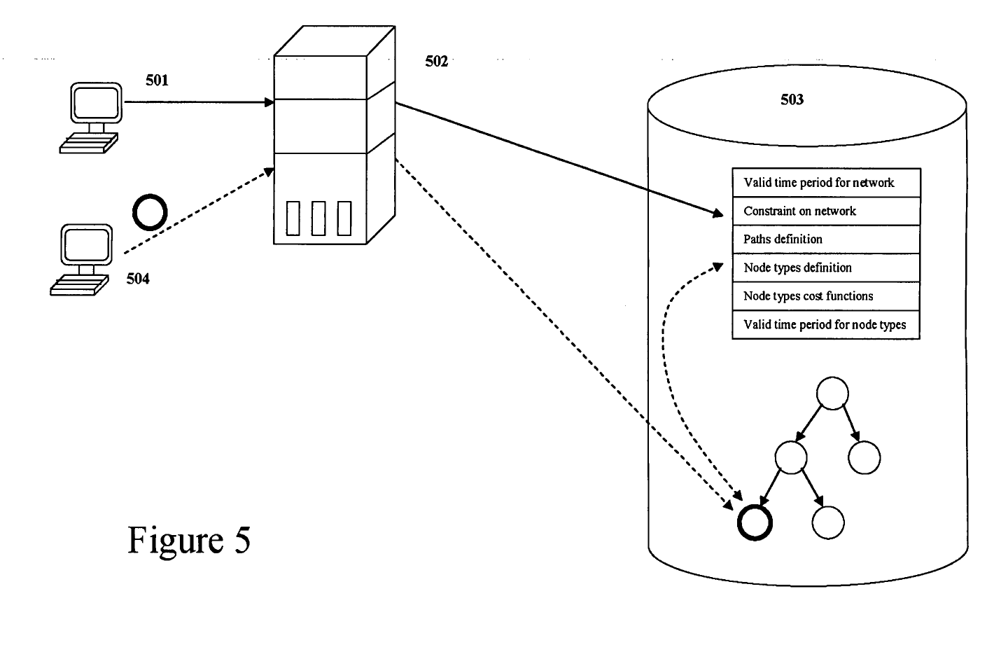

FIG. 5 illustrates an exemplary system for flexible cost management for a hierarchical network. A network is implemented with a software application on a server 502. The server 502 would receive from a user 501 the parameters for the network and its nodes (FIG. 3, steps 301-306). The parameters are stored in a database 503. The server 502 would also preserve the node referencing information at each level of the network in the database 503. When a user 504 wants to add a new node to the hierarchical network the server 502 adds the node for the second user 504 to the network (step 307). The server 502 then retrieves the stored parameters from the database 503, and calculates the cost for the added node, other affected nodes, and the network (steps 308-313). When the specified time period for the cost functions for the network or any of its nodes is triggered (step 314), the server 302 retrieves the stored parameters valid for the current time period from the database 503 and recalculates the costs of the nodes in the network and the cost of the network (steps 315-316).

Although the flexible cost management system is described as above with FIG. 5, one of ordinary skill in the art will understand that other system configurations are possible, depending on the application, without departing from the spirit and scope of the invention.

Foregoing described embodiments of the invention are provided as illustrations and descriptions. They are not intended to limit the invention to precise form described. In particular, it is contemplated that functional implementation of invention described herein may be implemented equivalently in hardware, software, firmware, and/or other available functional components or building blocks, and that networks may be wired, wireless, or a combination of wired and wireless. Other variations and embodiments are possible in light of above teachings, and it is thus intended that the scope of invention not be limited by this Detailed Description, but rather by Claims following or as amended or added in this or related application.

We claim:

1. A computer implemented method for flexible cost and constraint assignment for a hierarchical network comprising a plurality of nodes, comprising the steps of:
(a) defining one or more constraints on a total cost for the hierarchical network;
(b) defining a path and types of nodes for the hierarchical network; and
(c) defining a cost function for each node in the hierarchical network, wherein the cost function depends on a cost function of the node's parent node, cost functions for the node's child nodes, and the type of the node.

2. The method of claim 1, wherein the one or more constraints on the total cost for the hierarchical network comprises a valid time period.

3. The method of claim 1, wherein the cost function for each node further depends on a valid time period for a cost of the node.

4. The method of claim 1, wherein the cost function for each node further depends on one or more user definable criteria.

5. The method of claim 1, wherein the hierarchical network comprises a social network, wherein the pluralities of nodes represent users of the hierarchical network.

6. The method of claim 1, wherein the defined path comprises definitions of a starting node and an ending node for the path.

7. The method of claim 1, further comprising:
(d) adding a new node to the hierarchical network;
(e) identifying parameters for the added node, wherein the parameters comprises a node type, hierarchical level, and a path relationship with other nodes in the hierarchical network;
(f) identifying one or more cost functions matching the parameters for the added node;
(g) validating a time period for the added node according to the identified cost functions;
(h) calculating a cost for the added node according to the identified cost functions;
(i) calculating costs of other affected nodes in the hierarchical network; and
(j) calculating the total cost for the hierarchical network.

8. The method of claim 7, further comprising:
(k) determining that the valid time period has been triggered;
(l) recalculating the costs of each node in the hierarchical network; and
(m) recalculating the costs of the hierarchical network.

9. A computer readable medium with program instructions for flexible cost and constraint assignment for a hierarchical network comprising a plurality of nodes, comprising the instructions for:
(a) defining one or more constraints on a total cost for the hierarchical network;
(b) defining a path and types of nodes for the hierarchical network; and
(c) defining a cost function for each node in the hierarchical network, wherein the cost function depends on a cost function of the node's parent node, cost functions for the node's child nodes, and the type of the node.

10. A system, comprising:
a server for receiving parameters for a hierarchical network, wherein the parameters comprises:
one or more constraints on a total cost for the hierarchical network,
a path and types of nodes for the hierarchical network, and
a cost functions for each node in the hierarchical network, wherein the cost function depends on a cost function of the node's parent node, cost functions for the node's child nodes, and the type of the node; and
a database for storing the received parameters.

11. The system of claim 10, wherein the parameters further comprises one or more of the following:
a valid time period for the total cost of the network;
a valid time period for a cost of the node; and
one or more user definable criteria.

12. The system of claim 10, wherein the server:
adds a new node to the hierarchical network;
identifies parameters for the added node, wherein the parameters comprises a node type, hierarchical level, and a path relationship with other nodes in the hierarchical network;
retrieving the stored parameters from the database;
identifies one or more cost functions matching the parameters for the added node;
validates a time period for the added node according to the identified cost functions;
calculates a cost for the added node according to the identified cost functions;
calculates costs of other affected nodes in the hierarchical network; and
calculates the total cost for the hierarchical network.

13. The system of claim 12, wherein the server further:
determines that the valid time period has been triggered;
recalculates the costs of each node in the hierarchical network; and
recalculates the costs of the hierarchical network.
